(19) United States
(12) Patent Application Publication
(10) Pub. No.: US 2026/0206543 A1
(43) Pub. Date: Jul. 16, 2026

(54) METHOD OF MANUFACTURING SEMICONDUCTOR DEVICE

(71) Applicant: eMemory Technology Inc., Hsinchu (TW)

(72) Inventors: Cheng-Yen SHEN, Hsinchu County (TW); Tsung-Mu LAI, Hsinchu County (TW)

(21) Appl. No.: 19/379,758

(22) Filed: Nov. 5, 2025

Related U.S. Application Data
(60) Provisional application No. 63/719,167, filed on Nov. 12, 2024.

(51) Int. Cl. H01L 21/66

(52) U.S. Cl. CPC H10P 74/203

(57) ABSTRACT

A method of manufacturing a semiconductor device is provided and includes steps: forming a first charge-trapping layer on a first oxide layer on a first wafer in a lot of wafers by a deposition process; obtaining a first uniformity profile of the first charge-trapping layer; determining a first feed forward compensation information of the first wafer based on at least one of the first uniformity profile and a target uniformity profile; selecting a first process recipe in multiple process recipes based on the first feed forward compensation information; and forming a second oxide layer, according to the first process recipe, by a first oxidation process that consumes a portion of the first charge-trapping layer.

### CROSS-REFERENCE TO RELATED APPLICATION

The present application claims priority to U.S. Provisional Patent Application No. 63/719,167, filed on Nov. 12, 2024, which is incorporated by reference herein in its entirety.

### BACKGROUND

### Description of Related Art

While oxide-nitride-oxide (ONO) stacks are used effectively as either charge storage layers (like in silicon-oxide-nitride-oxide-silicon (SONOS) transistors) or as isolation between gates (in split-gate flash memory), quality for trapping charges in SONOS structures lies in the silicon nitride (SiN) thin film. Its non-uniform stoichiometry and lack of optimization across its thickness presents a significant challenge.

### SUMMARY

One aspect of the present disclosure is to provide a method of manufacturing a semiconductor device, including the following operations: forming a first charge-trapping layer on a first oxide layer on a first wafer in a lot of wafers by a deposition process; obtaining a first uniformity profile of the first charge-trapping layer; determining a first feed forward compensation information of the first wafer based on at least one of the first uniformity profile and a target uniformity profile; selecting a first process recipe in multiple process recipes based on the first feed forward compensation information; and forming a second oxide layer, according to the first process recipe, by a first oxidation process that consumes a portion of the first charge-trapping layer.

In some embodiments, the method further includes removing the second oxide layer; and forming a third oxide layer on the first charge-trapping layer.

In some embodiments, determining the first feed forward compensation information includes comparing thicknesses of the first charge-trapping layer at different locations in the first uniformity profile; and determining the first feed forward compensation information that compensation is greater for locations with first thicknesses than for locations with second thicknesses, the first thicknesses being greater than the second thicknesses.

In some embodiments, the first process recipe at least includes heating temperatures of multiple heating elements. Selecting the first process recipe based on the first feed forward compensation information includes selecting a process recipe that has heating temperatures of heating elements corresponding to the locations with the first thicknesses that are higher than heating temperatures of heating elements corresponding to the locations with the second thicknesses.

In some embodiments, the method further includes adjusting positions of multiple heating elements situated above the first charge-trapping layer according to the first uniformity profile.

In some embodiments, determining the first feed forward compensation information includes comparing thicknesses of the first charge-trapping layer at different locations in the first uniformity profile with a target thickness in the target uniformity profile to generate thickness differences; and determining the first feed forward compensation information that heat compensation is greater for locations with larger thickness differences than for locations with smaller thickness differences.

In some embodiments, multiple heating elements are situated above the first wafer. Selecting the first process recipe based on the first feed forward compensation information includes selecting a process recipe that has heating temperatures of heating elements corresponding to the locations with the larger thickness differences that are higher than heating temperatures of heating elements corresponding to the locations with the smaller thickness differences.

In some embodiments, determining the first feed forward compensation information further includes comparing an average thickness of the first charge-trapping layer in the first uniformity profile with a target average thickness in the target uniformity profile to generate an average thickness difference; and determining gas flow compensation in the first feed forward compensation information according to the average thickness difference.

In some embodiments, selecting the first process recipe based on the first feed forward compensation information further includes selecting the process recipe that has a gas flow rate and a corresponding process duration that match the gas flow compensation.

In some embodiments, the first process recipe includes at least one of heating temperatures of multiple heating elements situated above the first wafer, a process duration, and a flow rate of a gas that reacts with the first charge-trapping layer.

In some embodiments, the method further includes forming a second charge-trapping layer on a third oxide layer on a second wafer in the lot of wafers by the deposition process; obtaining a second uniformity profile of the second charge-trapping layer; determining a second feed forward compensation information of the second wafer based on the second uniformity profile and the target uniformity profile; selecting a second process recipe in multiple process recipes based on the second feed forward compensation information; and forming, according to the second process recipe, a fourth oxide layer by a second oxidation process that consumes a portion of the second charge-trapping layer.

In some embodiments, an average thickness of the first charge-trapping layer in the first uniformity profile and an average thickness of the second charge-trapping layer in the second uniformity profile are substantially the same with each other. The first process recipe and the second process recipe are the same.

In some embodiments, determining the first feed forward compensation information includes: comparing an average thickness of the first charge-trapping layer in the first uniformity profile with an average target thickness in the target uniformity profile to generate a first average thickness difference; and determining the first feed forward compensation information according to the first average thickness difference. Determining the second feed forward compensation information includes comparing an average thickness of the second charge-trapping layer in the second uniformity profile with the average target thickness to generate a second average thickness difference; and determining the second feed forward compensation information according to the second average thickness difference.

In some embodiments, when the first average thickness difference is smaller than the second average thickness difference, the selecting the first process recipe includes selecting a process recipe corresponding to a first reaction rate of consuming the first charge-trapping layer, and the selecting the second process recipe includes selecting a process recipe corresponding to a second reaction rate of consuming the second charge-trapping layer. The first reaction rate is slower than the second reaction rate.

In some embodiments, the method further includes when a thickness of the first charge-trapping layer at a location on the first wafer is different from a thickness of the second charge-trapping layer at the same location on the second wafer, adjusting process parameters for forming the fourth oxide layer from values in the first process recipe to values in the second process recipe.

In some embodiments, a thickness of a remaining portion of the first charge-trapping layer and a thickness of a remaining portion of the second charge-trapping layer are the same with each other.

Another aspect of the present disclosure is to provide a method of measuring a semiconductor device, including the following operations: obtaining multiple uniformity profiles of deposited layers in wafers of a lot; determining feed forward compensation information according to multiple thickness mapping profiles generated by comparing the uniformity profiles with a target uniformity profile; and tuning process parameters in oxidation process based on the feed forward compensation information to consume portions of the deposited layers in the wafers.

In some embodiments, comparing the uniformity profiles with the target uniformity profile includes comparing average thicknesses of deposited layers in the wafers with a target thickness to generate thickness differences in the thickness mapping profiles.

In some embodiments, comparing the uniformity profiles with the target uniformity profile includes comparing thicknesses of the deposited layer at different locations in each of the uniformity profiles with a target thickness in the target uniformity profile to generate a corresponding one in the thickness mapping profiles.

In some embodiments, tuning the process parameters in the oxide processes includes adjusting the process parameters according to a process recipe selected from multiple process recipes that matches the feed forward compensation information.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method, in accordance with some embodiments of the present disclosure.

FIG. 2 is a schematic diagram of a semiconductor device, in accordance with some embodiments of the present disclosure.

FIG. 3 is a schematic diagram of a semiconductor device corresponding to FIG. 2, in accordance with some embodiments of the present disclosure.

FIG. 4 is a schematic diagram of a wafer having the semiconductor device corresponding to FIG. 3, in accordance with some embodiments of the present disclosure.

FIG. 5 is a schematic diagram of a semiconductor device corresponding to FIGS. 2-4, in accordance with some embodiments of the present disclosure.

FIG. 6 is a schematic diagram of a semiconductor device corresponding to FIG. 5, in accordance with some embodiments of the present disclosure.

FIG. 7 is a schematic diagram of a semiconductor device corresponding to FIG. 6, in accordance with some embodiments of the present disclosure.

### DETAILED DESCRIPTION

The spirit of the present disclosure will be discussed in the following drawings and detailed description, and those of ordinary skill in the art will be able to change and modify the teachings of the present disclosure without departing from the spirit and scope of the present disclosure.

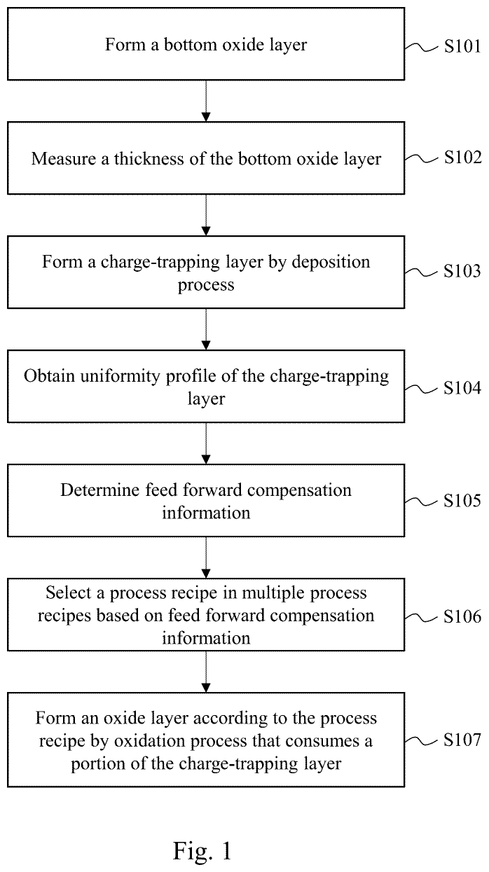

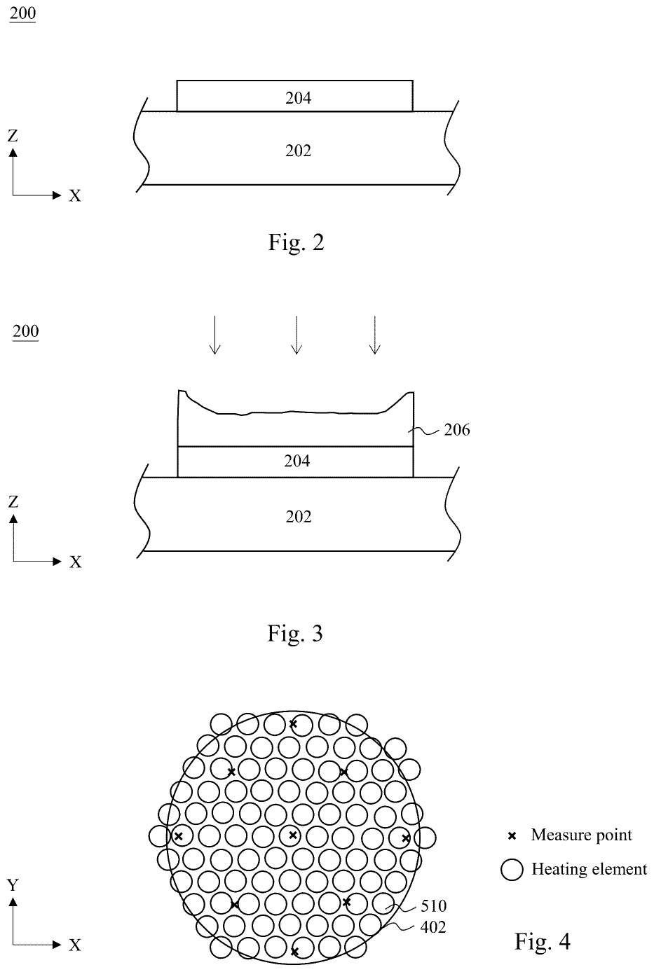

Reference is now made to FIG. 1. FIG. 1 is a flowchart of a method M100, in accordance with some embodiments of the present disclosure. It should be understood that there can be additional operations before, during, and after the process as shown in FIG. 1, and for additional embodiments of the method M100, some operations as described as follows can be replaced or eliminated. The method M100 includes operations S101-S107 described as follows by reference to FIG. 2 to FIG. 7. In some embodiments, the method M100 fabricates a semiconductor device 200 having a silicon-oxide-oxynitride-oxide-silicon (SONOS) structure composed of multiple thin films.

In operation S101, an oxide layer 204 is formed on a substrate 202 as a bottom layer of the semiconductor device 200 as shown in FIG. 2,. In some embodiments, the oxide layer 204 is formed or deposited by any suitable means including, for example, being thermally grown or deposited using chemical vapor deposition (CVD). In another embodiment, the oxide layer 204 is grown in an ISSG (In-Situ Steam Generation) chamber with a radical oxidation using a reaction between oxygen (O₂) and hydrogen (H₂) on the substrate 202.

In some embodiments, the substrate 202 may include any known silicon-based semiconductor material including silicon, silicon-germanium, silicon-on-insulator, or silicon-on-sapphire substrate. Alternatively, the substrate 202 may include a silicon layer formed on a non-silicon-based semiconductor material, such as gallium-arsenide, germanium, gallium-nitride, or aluminum-phosphide. In certain embodiments, the substrate 202 is a doped or undoped silicon substrate. The oxide layer 204 may include a relatively thin layer of silicon dioxide.

After forming the bottom oxide layer 204, during operation S102, a thickness of the oxide layer 204 is measured to check whether it is within the spec of process. When the property of the oxide layer 204 matches the process standard, operation S103 is performed.

In operation S103, as illustratively shown in FIG. 3, a deposited layer 206 is formed by the deposition process as a charge-trapping layer in the semiconductor device 200. In some embodiments, the semiconductor device 200 comprises and functions as at least one transistor. In some embodiments, the deposited layer 206 includes silicon nitride (SiN). The deposited layer 206 is deposited through CVD in a reaction chamber, with plasma-enhanced CVD (PECVD) preferred for its low-temperature compatibility. Silane (SiH₄) and ammonia (NH₃) precursors are introduced into the reaction chamber with a carrier gas, like nitrogen. Radio frequency (RF) power generates a plasma, decomposing the gases and depositing the SiN film onto the oxide layer 204.

For illustration, “edge-thick, center-thin” thickness non-uniformity of the deposited layer 206 is observed the semiconductor device 200. In some cases, the semiconductor device 200 is formed on a wafer 402 amid other wafers in a lot. With such arrangement, precursor gases (silane, ammonia, etc.) entering the reaction chamber are consumed during the deposition process. Edges of wafers may be exposed to a higher concentration of these fresh gases than central areas of the wafers, leading to a higher deposition rate at the edges.

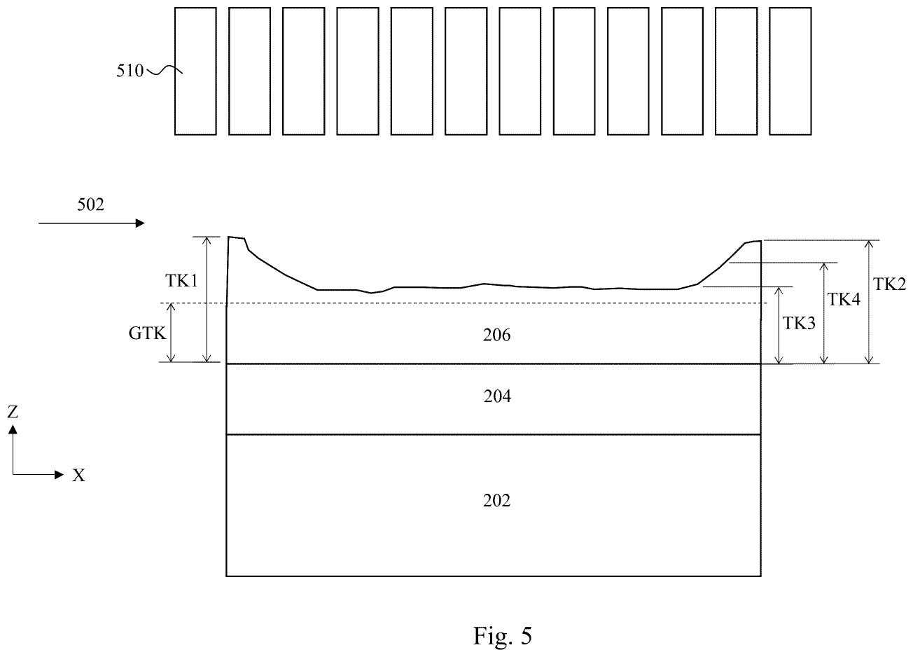

In order to unify thickness of the deposited layer 206, during operation S104, a uniformity profile of the deposited layer 206 is obtain through measuring thicknesses of the deposited layer 206 at different locations. For example, as shown in FIG. 4 to FIG. 5 that are schematic diagrams of the wafer having the semiconductor device corresponding to FIG. 3, the thickness of the deposited layer 206 at each measure point is measured as shown in FIG. 5 and the position of corresponding measure point is recorded for generating the uniformity profile. In some embodiments, the uniformity profile is referred to as a thickness mapping profile.

As shown in FIG. 5, the two edges have thicknesses TK1-TK2 that are greater than a thickness TK3 of a central region. In some embodiments, thickness of other measure point could be obtained for more profound uniformity profile, for example, a peripheral point has a thickness TK4 ranging between the thicknesses TK2 and TK3.

Furthermore, an oxidation process will be performed to the deposited layer 206 to consume portion of it and to unify remaining portion of the deposited layer 206. In some embodiments, specific process parameters of the oxidation that are determined for specific thickness are referred to as process recipes. In some embodiments, one of the process parameters in the process recipe is the heating temperature for the oxidation.

For example, as shown in both FIG. 4 and FIG. 5, the wafer 402 is put into the ISSG chamber which is equipped with multiple heating elements 510 situated above the wafer 402 and operate as a radiant energy assembly. In some embodiments, the heating elements 510 are configured to be independently controlled to provide for extremely uniform or non-uniform heating of wafer 402, as is desired according to the process. In one embodiment, the heating elements 510 are generally grouped into concentric zones. In this manner, temperature may be varied across the radius of the wafer 402 or desired temperature map. It is contemplated that the granularity and symmetry of thermal control may be more or less as desired for a particular process. In such cases, carefully controlling the temperature may achieve a desired control of oxide growth in the subsequent step S107.

In operation S105, a feed forward compensation information of the wafer 402 is determined based on at least one of the first uniformity profile and a target uniformity profile. In some embodiments, prior to forming an oxide layer in the subsequent step, the feed forward compensation information is generate based on output of the preceding step. For instance, the thickness of the deposited layer 206 formed in step S103 is used to optimize the process parameters for the subsequent step S106, aiming to achieve target standard. Unlike feedback approaches that adjust the manufacturing tool after step S106 based on the performance of the current lot to mitigate issues in the lot, the configurations of the present application prevent the current running lot from being wasted. Instead, the present application leverages the information obtained from the preceding step to proactively adjust the manufacturing tool, enabling an optimized process for the current lot. This increases manufacturing efficiency and optimizes fabrication costs.

According to some embodiments, determining the feed forward compensation information includes comparing thicknesses TK1-TK4 of the deposited layer 206 at different locations in the uniformity profile with a target thickness GTK in the target uniformity profile to generate thickness differences, as shown in FIG. 5. In some embodiments, the target thickness GTK is a desired thickness of the deposited layer 206 in the semiconductor device 200. In some embodiments, based on the thickness differences, the feed forward compensation information is determined that heat compensation is greater for locations with larger thickness differences than for locations with smaller thickness differences. For example, as shown in FIG. 5, the heat compensation is greater for the edges than for the central region.

Next, in step S106, a process recipe in multiple process recipes based on feed forward compensation information is selected. For example, the first process recipe has the heating temperature of all heating elements 510 are set to be the same, while the second process recipe has the heating temperatures of heating elements 510 corresponding to the locations with the larger thickness differences (e.g., edges) that are higher than heating temperatures of heating elements 510 corresponding to the locations with the smaller thickness differences (e.g., central region). In order to meet the feed forward compensation information, the second process recipe is selected for the subsequent steps.

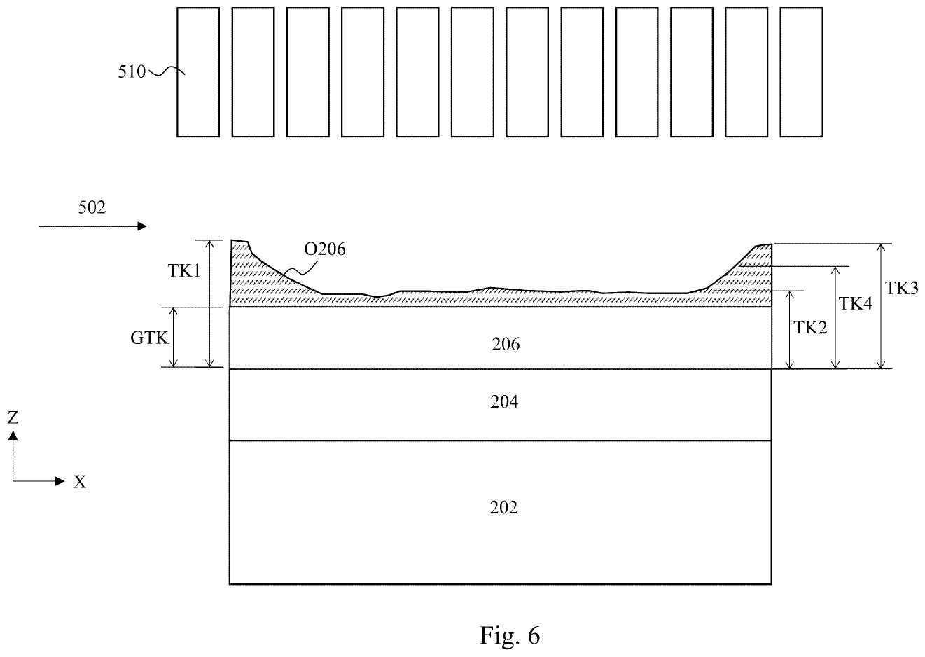

In step S107, top portion of the deposited layer 206 in FIG. 5 is consumed to form an oxide layer O206 in FIG. 6 according to the selected process recipe, which is induced by heat and the gas flow 502 during the oxidation process. Specifically, as shown in FIG. 6, gas flow 502 mixed with an oxygen-containing gas and a hydrogen-containing gas is fed into the ISSG reaction chamber in which the semiconductor device 200 is located. The oxygen-containing gas and the hydrogen-containing gas are caused to react to form moisture or steam (H₂O) in the reaction chamber. Consequently, the remaining portion of the deposited layer 206 has a unified thickness equal to the target thickness GTK.

As illustratively shown in FIG. 6, during ISSG wet oxidation, the top region of the deposited layer 206 (e.g., SiN film) is selectively transformed into a stable oxide layer O206 (e.g., SiO₂ film). This conversion shifts the sensitive SiN variations away from the active region, enhancing interface quality and dielectric performance. In some embodiments, the oxide layer O206 is kept and configured to be the top oxide layer of the SONOS structure of the semiconductor device 200.

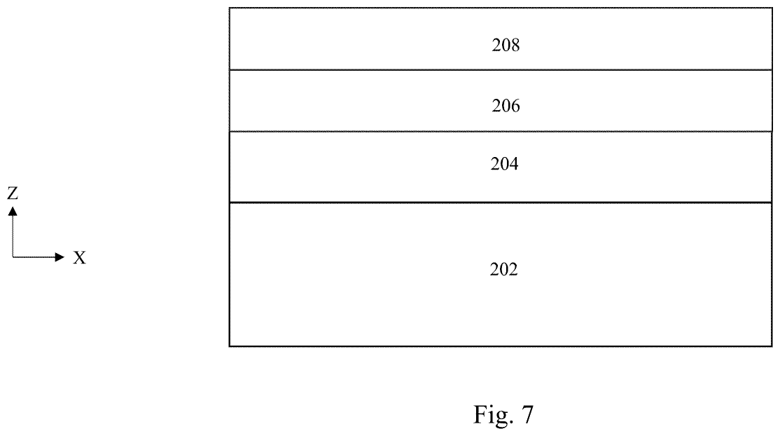

In other embodiments, the method M100 further includes removing the oxide layer O206 by some suitable process, for example, chemical mechanical polishing/planarization (CMP) process, and also includes forming a deposited layer on the deposited layer 206. As shown in FIG. 7 that illustrates a schematic diagram of a semiconductor device corresponding to FIG. 6, the oxide layer O206 is removed and a deposited layer 208 is formed on the deposited layer 206 by suitable process, for example, CVD. In some embodiments, the deposited layer 208 is configured to be the top oxide layer of the SONOS structure of the semiconductor device 200.

In other embodiments, instead of comparing the measured thicknesses with the target thickness, thicknesses (e.g., TK1, TK2, TK3, TK4) at different locations in the uniformity profile of the deposited layer 206 are compared with each other. Then, the feed forward compensation information is determined that compensation is greater for locations (e.g., edges) with thicker thicknesses than for locations (central region) with thinner thicknesses in step S105. Accordingly, the corresponding selected process recipe in step S106 has heating temperatures of heating elements 510 corresponding to the locations (central region) with the thicker thicknesses that are higher than heating temperatures of heating elements 510 corresponding to the locations with the thinner thicknesses.

Moreover, in some embodiments, the method M100 further includes the step of adjusting positions of the heating elements 510 situated above the deposited layer 206 according to the uniformity profile. For example, based on the gradient of the thickness of the deposited layer 206, the density of the heating elements 510 is higher for region with larger slope of thickness than for region with smaller slope of thickness.

In addition to tuning the heat temperature of the heating elements 510 in the oxidation process, the process parameters in process recipe for oxidation process also include a flow rate of the gas flow 502 and/or a process duration. In some embodiments, the determination of the feed forward compensation information includes gas flow compensation.

For example, with reference to FIG. 4, an average thickness of the deposited layer 206 is obtained based on the thicknesses of all the measure points of the wafer 402. The average thickness is further compared with target average thickness in the target uniformity profile to generate an average thickness difference. Then, the gas flow compensation in the feed forward compensation information is determined according to the average thickness difference. For example, when the gas flow compensation for larger average thickness difference is greater than for smaller average thickness difference. Correspondingly, a process recipe is selected and has the gas flow rate and the process duration that match the gas flow compensation.

For example, to match greater gas flow compensation, at least one of the gas flow rate and the process duration is tuned to be greater than those for smaller gas flow compensation, in order to consume more from the deposited layer 206 to achieve the target average thickness.

In some embodiments, the target average thickness is for all wafers in a process lot including multiple wafers. For the purpose of monitoring the manufacturing process, several wafers in the lot, for example, the method M100 is performed to the first wafer, the wafer at the one-third position in the lot, and the wafer at the two-thirds position in the lot. Average thicknesses of aforementioned wafers are compared with a target average thickness in the target thickness profile to generate average thickness differences. Then the feed forward compensation information for the wafers are determined according to the average thickness differences. In some embodiments, when the average thickness difference of the first wafer is smaller than that of the second wafer, the process recipe selected for the first wafer corresponds to a slower reaction rate of consuming the deposited layer. For example, the recipe has at least one of the lower temperature, the slower gas flow rate, and the longer reaction duration. On contrary, the process recipe selected for the second wafer corresponds to a faster reaction rate of consuming the deposited layer.

The configurations of selecting process recipes for wafers are similar to discussion mentioned before. Hence, the repetitious descriptions are omitted here.

In other embodiments, when an average thickness of the deposited layer 206 in the uniformity profile of the first wafer and an average thickness of the deposited layer 206 in the uniformity profile of another monitored wafer (e.g., the wafer at the one-third position in the lot) are substantially the same with each other, the process parameters of the process recipe remain for the first wafer to the wafer before the wafer at the two-thirds position in the lot. After that, it is determined whether the average thickness of the wafer at the two-thirds position in the lot is the same as that of the wafer at the one-third position in the lot. If the difference is huge, another process recipe is selected to perform step S107 for the wafer at the two-thirds position in the lot to the last wafer.

In some embodiments, through selecting proper process recipes to manipulate heating temperatures of the heating elements 510 spatially based on the thicknesses at different location of the single wafer and to control the gas flow rate and the reaction duration, oxide layers are formed correspondingly by consuming portions of the deposited layers, mitigating the variations in the thicknesses of the deposited layers. Accordingly, for example, a thickness of a remaining portion of the deposited layer 206 of the first wafer and a thickness of a remaining portion of the deposited layer 206 of the second wafer are substantially the same with each other, providing optimized deposited layers 206 across the whole lot in process.

This application proactively leverages preceding-step data to optimize the manufacturing tool for the current lot, preventing waste and enhancing efficiency. Unlike reactive feedback adjustments applied after processing a lot, this method strategically uses information from the preceding step. By selecting process recipes to spatially control heating element temperatures, gas flow rates, and reaction durations based on wafer thickness, oxide layer formation consumes portions of the deposited layers, mitigating thickness variations. This ensures deposited layer thickness uniformity across wafers, optimizing fabrication costs. Spatial control over the thickness gradient is therefore achieved, improving yield and throughput.

While the disclosure has been described by way of example(s) and in terms of the preferred embodiment(s), it is to be understood that the disclosure is not limited thereto. Those skilled in the art may make various changes, substitutions, and alterations herein without departing from the spirit and scope of the present disclosure. In view of the foregoing, it is intended that the present invention cover modifications and variations of this invention provided they fall within the scope of the following claims.

What is claimed is:

1. A method of manufacturing a semiconductor device, comprising:
forming a first charge-trapping layer on a first oxide layer on a first wafer in a lot of wafers by a deposition process;
obtaining a first uniformity profile of the first charge-trapping layer;
determining a first feed forward compensation information of the first wafer based on at least one of the first uniformity profile and a target uniformity profile;
selecting a first process recipe in a plurality of process recipes based on the first feed forward compensation information; and
forming a second oxide layer, according to the first process recipe, by a first oxidation process that consumes a portion of the first charge-trapping layer.

2. The method of claim 1, further comprising:
removing the second oxide layer; and
forming a third oxide layer on the first charge-trapping layer.

3. The method of claim 1, wherein determining the first feed forward compensation information comprises:
comparing thicknesses of the first charge-trapping layer at different locations in the first uniformity profile; and
determining the first feed forward compensation information that compensation is greater for locations with first thicknesses than for locations with second thicknesses, the first thicknesses being greater than the second thicknesses.

4. The method of claim 3, wherein the first process recipe at least comprises heating temperatures of a plurality of heating elements,
wherein selecting the first process recipe based on the first feed forward compensation information comprises:
selecting a process recipe that has heating temperatures of heating elements corresponding to the locations with the first thicknesses that are higher than heating temperatures of heating elements corresponding to the locations with the second thicknesses.

5. The method of claim 1, further comprising:
adjusting positions of a plurality of heating elements situated above the first charge-trapping layer according to the first uniformity profile.

6. The method of claim 1, wherein determining the first feed forward compensation information comprises:
comparing thicknesses of the first charge-trapping layer at different locations in the first uniformity profile with a target thickness in the target uniformity profile to generate thickness differences; and
determining the first feed forward compensation information that heat compensation is greater for locations with larger thickness differences than for locations with smaller thickness differences.

7. The method of claim 6, wherein a plurality of heating elements are situated above the first wafer,
wherein selecting the first process recipe based on the first feed forward compensation information comprises:
selecting a process recipe that has heating temperatures of heating elements corresponding to the locations with the larger thickness differences that are higher than heating temperatures of heating elements corresponding to the locations with the smaller thickness differences.

8. The method of claim 6, wherein determining the first feed forward compensation information further comprises:
comparing an average thickness of the first charge-trapping layer in the first uniformity profile with a target average thickness in the target uniformity profile to generate an average thickness difference; and
determining gas flow compensation in the first feed forward compensation information according to the average thickness difference.

9. The method of claim 8, wherein selecting the first process recipe based on the first feed forward compensation information further comprises:
selecting the process recipe that has a gas flow rate and a corresponding process duration that match the gas flow compensation.

10. The method of claim 1, wherein the first process recipe comprises at least one of heating temperatures of a plurality of heating elements situated above the first wafer, a process duration, and a flow rate of a gas that reacts with the first charge-trapping layer.

11. The method of claim 1, further comprising:
forming a second charge-trapping layer on a third oxide layer on a second wafer in the lot of wafers by the deposition process;
obtaining a second uniformity profile of the second charge-trapping layer;
determining a second feed forward compensation information of the second wafer based on the second uniformity profile and the target uniformity profile;
selecting a second process recipe in the plurality of process recipes based on the second feed forward compensation information; and
forming, according to the second process recipe, a fourth oxide layer by a second oxidation process that consumes a portion of the second charge-trapping layer.

12. The method of claim 11, wherein an average thickness of the first charge-trapping layer in the first uniformity profile and an average thickness of the second charge-trapping layer in the second uniformity profile are substantially the same with each other,
the first process recipe and the second process recipe are the same.

13. The method of claim 11, wherein determining the first feed forward compensation information comprises:
comparing an average thickness of the first charge-trapping layer in the first uniformity profile with an average target thickness in the target uniformity profile to generate a first average thickness difference; and
determining the first feed forward compensation information according to the first average thickness difference;
wherein determining the second feed forward compensation information comprises:
comparing an average thickness of the second charge-trapping layer in the second uniformity profile with the average target thickness to generate a second average thickness difference; and
determining the second feed forward compensation information according to the second average thickness difference.

14. The method of claim 13, wherein when the first average thickness difference is smaller than the second average thickness difference,
selecting the first process recipe comprises selecting a process recipe corresponding to a first reaction rate of consuming the first charge-trapping layer, and
selecting the second process recipe comprises selecting a process recipe corresponding to a second reaction rate of consuming the second charge-trapping layer,
wherein the first reaction rate is slower than the second reaction rate.

15. The method of claim 11, further comprising:
when a thickness of the first charge-trapping layer at a location on the first wafer is different from a thickness of the second charge-trapping layer at the same location on the second wafer,
adjusting process parameters for forming the fourth oxide layer from values in the first process recipe to values in the second process recipe.

16. The method of claim 11, wherein a thickness of a remaining portion of the first charge-trapping layer and a thickness of a remaining portion of the second charge-trapping layer are the same with each other.

17. A method, comprising:
obtaining a plurality of uniformity profiles of deposited layers in wafers of a lot;
determining feed forward compensation information according to a plurality of thickness mapping profiles generated by comparing the plurality of uniformity profiles with a target uniformity profile; and
tuning process parameters in oxidation process based on the feed forward compensation information to consume portions of the deposited layers in the wafers.

18. The method of claim 17, wherein comparing the plurality of uniformity profiles with the target uniformity profile comprises:
comparing average thicknesses of deposited layers in the wafers with a target thickness to generate thickness differences in the plurality of thickness mapping profiles.

19. The method of claim 17, wherein comparing the plurality of uniformity profiles with the target uniformity profile comprises:
comparing thicknesses of the deposited layer at different locations in each of the uniformity profiles with a target thickness in the target uniformity profile to generate a corresponding one in the plurality of thickness mapping profiles.

20. The method of claim 17, wherein tuning the process parameters in the oxide processes comprises:
adjusting the process parameters according to a process recipe selected from a plurality of process recipes that matches the feed forward compensation information.
